(19) United States
(12) Patent Application Publication
(10) Pub. No.: US 2002/0133245 A1
(43) Pub. Date: Sep. 19, 2002

(54) Display panel identification method for notebook computer by using audio signal

(76) Inventors: Kuo-Chih Lee, Taipei (TW); Chen-Jung Huang, Taipei (TW)

Correspondence Address: BIRCH STEWART KOLASCH & BIRCH, PO BOX 747, FALLS CHURCH, VA, 22040-0747, US

(21) Appl. No.: 09/772,942

(22) Filed: Jan. 31, 2001

(51) Int. Cl. G06F 17/00; H03G 3/00

(52) U.S. Cl. 700/94; 381/61

(57) ABSTRACT

A method for identifying at least a display panel of a notebook computer by processing audio signals is to incorporate a resistor on the main circuit board of the notebook computer, and different resistors in different display panels for deriving specific voltages. A control unit generates a strapping signal to pass through the voltage derivation circuit to an audio CODEC. The audio CODEC reads the voltage and transforms it into digital value and finds out the corresponding panel ID with a matching table. Therefore, the corresponding display panel can be identified.

### BACKGROUND OF THE INVENTION

1. Field of Invention

The present invention generally relates to a method for identifying display panels of a notebook computer during assembly, and more particularly relates to a method for identifying display panels of a notebook computer by means of processing audio signal with an audio coder/decoder.

2. Related Art

In conventional assembly process of notebook computers, the display panels are identified by pins of a connector. For example, three pins can provide eight (2³) combinations of identification code as panel IDs. If more panel IDs are needed, then more pins are required.

As we know, a coder/decoder (CODEC) is capable of encoding analog signals to digital signal, and, from the other end, decoding digital signal to analog signal. Therefore, a CODEC is suitable for transferring analog signals to digital data. It is therefore feasible to utilize the I/O channel of audio CODEC of a notebook computer for identifying the panel IDs by means of audio signals.

### SUMMARY OF THE INVENTION

It is therefore an object of the present invention to provide a method for identifying display panels of a notebook computer by means of an audio coder/decoder.

The present invention provides a resistor on the main circuit board of the notebook computer, and a plurality of different resistors incorporated in different display panels for deriving specific voltages. A control unit generates a strapping signal to pass through the voltage derivation circuit of aforesaid resistors of main circuit board and display panel to an audio CODEC. The audio CODEC reads the voltage and transforms it into digital value and finds out the corresponding panel ID with a matching table. Therefore, the corresponding display panel can be identified.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a circuit diagram showing components of the present invention; and

FIG. 2 is a flowchart showing the method of the present invention for identifying display panels of a notebook computer.

### DETAILED DESCRIPTION OF THE INVENTION

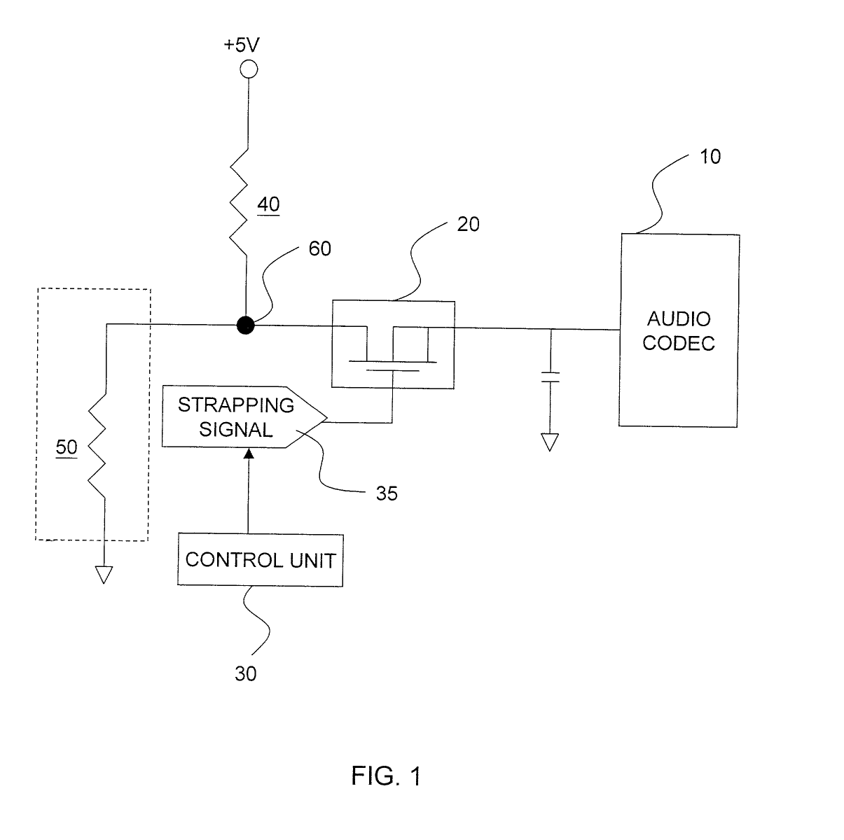

FIG. 1 shows a circuit diagram of the present invention. It includes an audio CODEC 10, for example, a 18-bit stereo CODEC incorporating an analog/digital converter and a digital/analog converter. A transistor switch 20 is controlled by a control unit 30 to provide a strapping signal passing through a voltage derivation circuit composed of a first transistor 40 and a second resistor 50. The transistor switch 20 turns on and off the strapping signal.

The first resistor 40 is a resistor incorporated in the main circuit board of the notebook computer. The second resistor 50 is the respective resistor incorporated in each display panel. Therefore, different display panel will provide a specific voltage signal to the audio CODEC 10, which will then be transformed into digital value by the audio CODEC 10. And, according to a matching table stored in the system software, i.e., BIOS, of the main circuit board, the corresponding ID of the panel can be obtained.

Substantially, any audio input ports, e.g., AUX-R, AUX-L, LIN IN-R, LINE in-L, of the audio CODEC 10, can be used as input port of the voltage signal, and connected to the communication port, for example, COM1 of the notebook computer.

In order to decode panel IDs from the voltage values, a matching table, called “LCM Panel ID Table”, is established in the BIOS. The principle for establishing a matching table is described below with an example of identification of four display panels:

1. the first resistor 40 is 33 kΩ;

2. the voltage at the derivation point 60 is 0 to 2.5 volt;

3. the audio CODEC 10 is an 18-bit (2¹⁸=262144) stereo digital/analog converter.

Therefore, the increment for each resistor of panel is: 33 kΩ/4=8.25 kΩ;

the increment for voltage of each panel is: 2.5 V/4=0.625 V;

the increment of digital value from analog/digital converter (ADC) for each panel is 262144/4=65536;

As a result, the following LCM Panel ID Table can be obtained.

| Panel | | | |
|---|---|---|---|
| ID | 2^{nd} Resistor (Ω) | Voltage Derivation (V) | Value Range for ADC |
| ID1 | 0 ˜ 8.25 k | 0 ˜ O.625 | 0 ˜ 65535 |
| ID2 | 8.25 k ˜ 16.5 k | 0.625 ˜ 1.25 | 65536 ˜ 131072 |
| ID3 | l6.5 k ˜ 24.75 k | 1.25 ˜ 1.875 | 131073 ˜ 1996608 |
| ID4 | 24.75 k ˜ 33 k | 1.875 ˜ 2.5 | 1996609 ˜ 262144 |

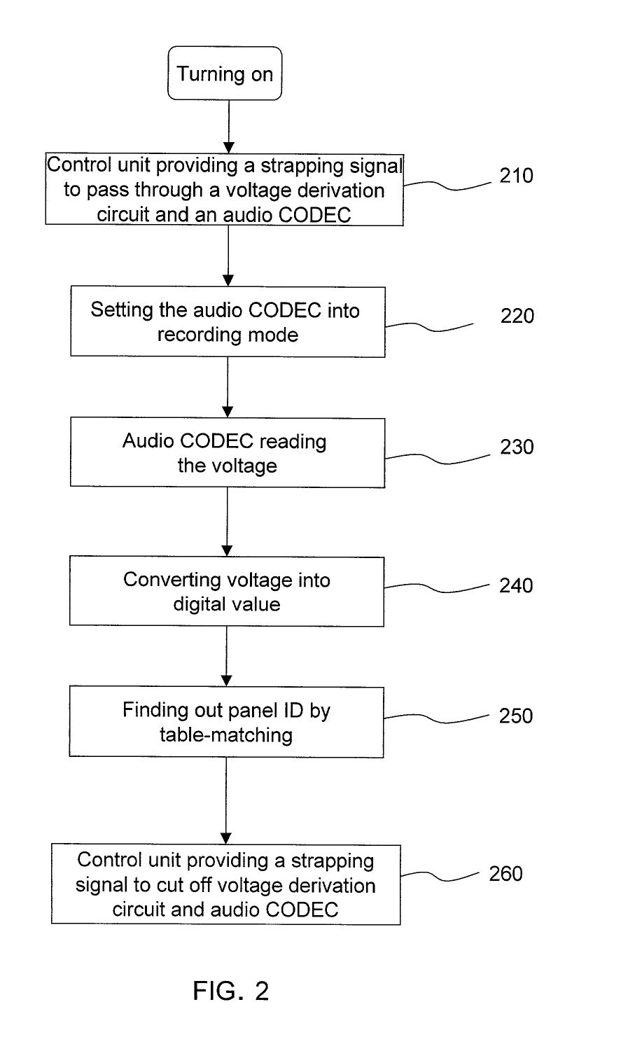

FIG. 2 shows a flowchart of the method for identifying display panels of a notebook computer according to the present invention. During assembling a notebook computer, the display panel ID has to be identified first. The steps are:

1. the control unit 30 providing a strapping signal 35 to pass through the voltage derivation circuit 60 and the audio CODEC 10 (step 210);

2. setting the audio input AUX-R of the audio CODEC 10 into recording mode (step 220);

3. audio CODEC 10 reading the voltage (step 230);

4. the audio CODEC 10 converting the voltage into digital value (step 240);

5. identifying panel ID by table-matching from the LCM Panel ID Table (step 250); and

6. the control unit 30 providing a strapping signal to cut off voltage derivation circuit 60 and audio CODEC 10 (step 260).

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for identifying at least a display panel of a notebook computer by processing audio signals, comprising steps of:
a) establishing a matching table defining a plurality of Panel IDs and digital values corresponding to a plurality of display panels;
b) a control unit providing a strapping signal to pass through a voltage derivation circuit and an audio CODEC;
c) setting the audio CODEC into recording mode;
d) the audio CODEC reading the derivation voltage;
e) the audio CODEC converting the voltage into digital value;
f) identifying panel ID by said matching table; and
g) the control unit providing a strapping signal to cut off voltage derivation circuit and the audio CODEC.

2. A method for identifying at least a display panel of a notebook computer by processing audio signals according to claim 1 wherein said voltage derivation circuit includes a first resistor incorporated in a main circuit board of the notebook computer, and a second resistor incorporated in the display panel.

3. A method for identifying at least a display panel of a notebook computer by processing audio signals according to claim 1 wherein said voltage derivation circuit further incorporates with a switch for turning on and off the voltage to said audio CODEC.

4. A method for identifying at least a display panel of a notebook computer by processing audio signals according to claim 1 wherein output of said voltage derivation circuit is connected to input port of said audio CODEC.

5. A method for identifying at least a display panel of a notebook computer by processing audio signals according to claim 1 wherein said matching table is stored in BIOS of said notebook computer.

6. A method for identifying at least a display panel of a notebook computer by processing audio signals according to claim 1 wherein said audio signals are analog signals.
